(19) United States
(12) Patent Application Publication
(10) Pub. No.: US 2011/0175512 A1
(43) Pub. Date: Jul. 21, 2011

(54) LIGHT EMITTING DIODE AND LIGHT SOURCE MODULE HAVING SAME

(75) Inventor: Chih-Ming LAI, Chu-Nan (TW)

(73) Assignee: FOXSEMICON INTEGRATED TECHNOLOGY, INC., Chu-Nan (TW)

(21) Appl. No.: 12/766,918

(22) Filed: Apr. 25, 2010

(30) Foreign Application Priority Data
Jan. 19, 2010 (CN) 201010300428.X

(51) Int. Cl. H01J 61/52; H01L 33/62; H01L 33/64

(52) U.S. Cl. 313/46; 257/99; 257/E33.066; 257/E33.075

(57) ABSTRACT

An exemplary light emitting diode includes a heat sink, an insulating layer, a positive electrode, a negative electrode, and a light emitting diode chip. The heat sink has a first surface, and the first surface includes a first portion and a second portion adjacent to the first portion. The insulating layer is arranged on the first portion of the first surface and has a second surface facing away from the heat sink. The positive electrode and the negative electrode are arranged on the second surface. The light emitting diode chip is mounted on the second portion and spaced from the positive electrode and the negative electrode, and the light emitting diode chip is electrically connected to the positive electrode and the negative electrode.

### TECHNICAL FIELD

The disclosure generally relates to light emitting diodes (LEDs), and particularly to an LED operating efficiently and a light source module using the LED.

### DESCRIPTION OF RELATED ART

In recent years, due to excellent light quality and high luminous efficiency, light emitting diodes (LEDs) have increasingly been used to substitute for cold cathode fluorescent lamps (CCFLs) as a light source of an illumination device.

Referring to FIG. 6, a typical LED 100 includes two metal electrodes 102, a housing 103, an LED chip 104, and an encapsulation layer 106. The housing 103 covers part of each metal electrode 102. The LED chip 104 is mounted on one of the metal electrodes 102 and electrically connected to the other metal electrode 102 via a wire (not labeled). The encapsulation layer 106 covers the LED chip 104. The LED 100 is mounted on a circuit board 120 when in use. The circuit board 120 applies electric current to the LED chip 104. The LED chip 104 emits light and generates heat. The light passes through the encapsulation layer 106 to illuminate an ambient environment. The heat is transferred to the circuit board 120 through the metal electrode 102 which the LED chip 104 is mounted on. However, the metal electrode 102 is used to apply electric current to the LED chip 104, as well as transfer heat from the LED chip 104. In such case, thermal resistance of the metal electrode 102 can be relatively high. The heat from the LED chip 104 may not be dissipated quickly; thus, light intensity of the LED 100 may be attenuated gradually, shortening the life thereof.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is cross-section of an LED, in accordance with a first embodiment.

FIG. 2 is cross-section of an LED, in accordance with a second embodiment.

FIG. 3 is cross-section of an LED, in accordance with a third embodiment.

FIG. 4 is cross-section of an LED, in accordance with a fourth embodiment.

FIG. 5 is cross-section of a light source module using a plurality of LEDs from FIG. 3.

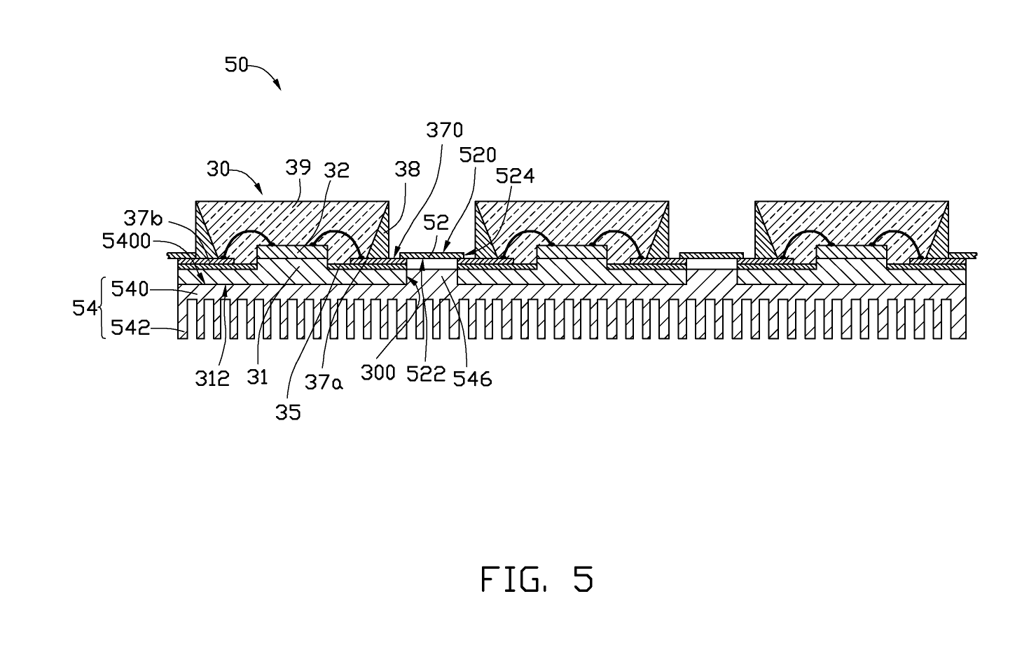

FIG. 6 is cross-section of a typical LED.

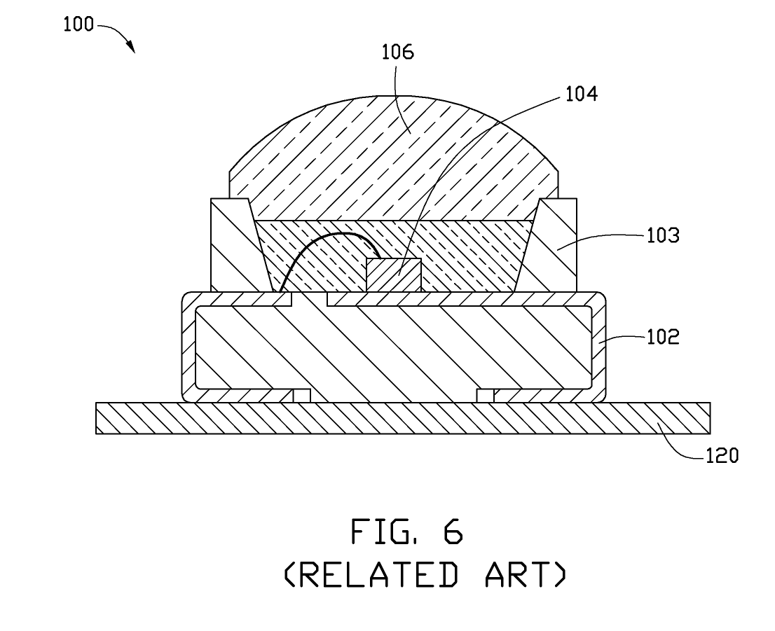

### DETAILED DESCRIPTION

Embodiments of the LEDs will now be described in detail below and with reference to the drawings.

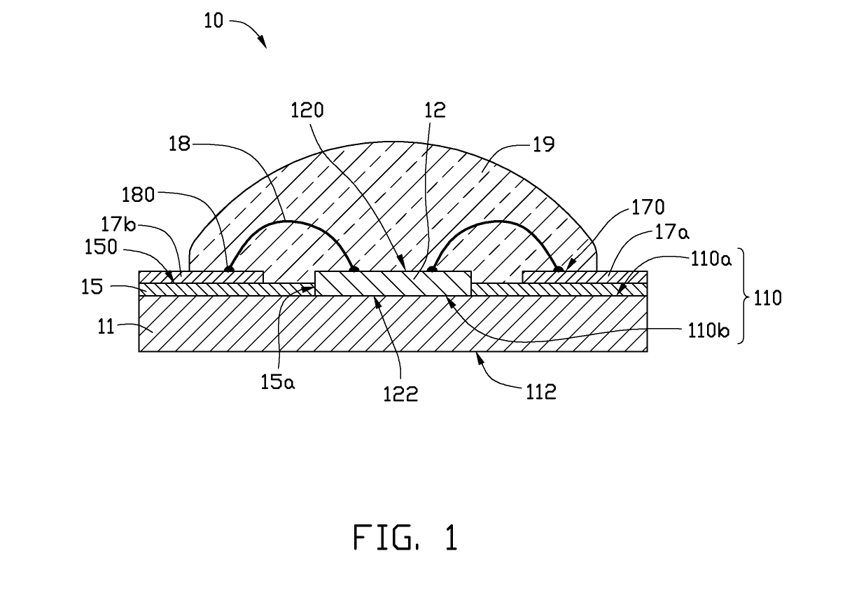

Referring to FIG. 1, an LED 10 in accordance with a first embodiment is shown. The LED 10 includes a heat sink 11, an LED chip 12, at least one insulating layer 15, a positive electrode 17a, a negative electrode 17b, and an encapsulation layer 19.

The heat sink 11 may have a general cuboid shape, a general cylindrical shape or a general disk shape, and includes a first surface 110 and a second surface 112 at two opposite sides thereof. The first surface 110 includes a first portion 110a and a second portion 110b. The second portion 110b is located at a central region of the first surface 110. The first portion 110a adjoins and surrounds the second portion 110b. The heat sink 11 is configured to dissipate heat from the LED chip 12. In this embodiment, the heat sink 11 can be made of metallic material with high thermal conductivity, such as aluminum, copper, or an alloy thereof, or another suitable metal or alloy. The heat sink 11 has a solid structure with no holes defined therein. Alternatively, the heat sink 11 may have a porous structure with a number of holes (not shown) uniformly distributed therein to in increase surface area contacting the air. Thus, heat dissipating efficiency of the heat sink 11 may be increased.

The LED chip 12 may be essentially made of phosphide such as AlₓIn_{y}Ga_{(1-x-y)}P(0≦x≦1, 0≦y≦1, x+y≦1) or arsenide, such as AlInGaAs, or another suitable material, for example nitrides such as InₓAl_{y}Ga_{(1-x-y)}N (0≦x≦1, 0≦y≦1, x+y≦1). The LED chip 12 may include a substrate (not labeled) made of intrinsic semiconductor or unintentionally doped semiconductor. A carrier concentration of the substrate is less than or equal to 5×10⁶ cm⁻³, or preferably less than or equal to 2×10⁶ cm⁻³. The substrate of the LED chip 12 with less carrier concentration may have lower conductivity; thus, electric current following through the substrate may be avoided. Accordingly, electric current applied to the LED chip 12 can be efficiently used, and the LED chip 12 emits light efficiently. The substrate of the LED chip 12 can be made of spinel, SiC, Si, ZnO, GaN, GaAs, GaP, or AlN. Alternatively, the substrate of the LED chip 12 may be made of material with high thermal coefficient and good electrical insulation property, such as diamond.

The LED chip 12 includes a light emitting surface 120 and a bottom surface 122 at two opposite sides thereof. In this embodiment, the LED chip 12 is arranged on the second portion 110b of the first surface 110, and can be attached to heat sink 11 directly. In one typical embodiment, a eutectic process can be applied when the LED chip 12 is attached to heat sink 11. The eutectic process can be applied by adhering the material of the LED chip 12 with the material of the heat sink 11 within an ultrasonic field and high temperature environment. Such adhesion can be achieved by melting, bonding, or fusing. In alternative embodiments, the LED chip 12 may be attached to the heat sink 11 via an adhesive layer (not shown). The adhesive layer can be coated on either or both of the bottom surfaces 122 and the second portion 110b of the first surface 110, before the LED chip 12 is attached to the heat sink 11. The adhesive layer may be made of metallic material selected from the group consisting of gold, tin, and silver; or the adhesive layer may be colloidal silver, or solder paste, or another suitable adhesive material.

The at least one insulating layer 15 is arranged on the first surface 110 of the heat sink 11, and may be made of material with low thermal conductivity and good electrical insulation property. The material for making the insulating layer 15 can be polyester (PET), polyimide (PI), polycarbonate (PC), polymethyl methacrylate (PMMA), polymer, silicone, epoxy, or spin on glass (SOG). Alternatively, the material can also be silicon oxide (SiO₂), silicon nitride (SiₓN_{y}), silicon oxynitride (SiON), titanium dioxide (TiO₂), titanium nitride (TiN), or aluminum oxide (AlₓO_{y}). In this embodiment, the LED 10 includes at least one insulating layer 15, and the insulating layer 15 has a second surface 150 facing away from the heat sink 11. The insulating layer 15 is annular with a through hole 15a defined in a central region of the second surface 150. The second portion 110b of the first surface 110 is exposed in the hole 15a. The LED chip 12 arranged on the second portion 110b extends all the way through the hole 15a. In alternative embodiments, the at least one insulating layer 15 may include two or more insulating layers 15, and the insulating layers 15 can be spaced from apart and surround the LED chip 12. In one typical example, the at least one insulating layer 15 may include two insulating layers 15 arranged at two opposite sides of the LED chip 12.

The positive electrode 17a and the negative electrode 17b are formed on a side of the insulating layer 15 facing away from the heat sink 11. In particular, the positive electrode 17a and the negative electrode 17b each are spaced from the LED chip 12. The LED chip 12 is electrically connected to the positive electrode 17a and the negative electrode 17b via two wires 18. Each wire 18 may be further connected to an exterior power supply (not shown) mounted on a circuit board (not shown) via the positive and negative electrodes 17a, 17b. Thereby, electric current can be applied to the LED chip 12. In this embodiment, the positive electrode 17a and the negative electrode 17b has a height relative to the second surface 150 the same as one another. The positive electrode 17a and the negative electrode 17b each have a third surface 170 coplanar with the light emitting surface 120 of the LED chip 12. Each wire 18 includes two distal ends 180. The two distal ends 180 of each wire 18 can be attached to the third surface 170 of the corresponding positive electrode 17a or negative electrode 17b and the light emitting surface 120 at a same height by wire bonding. In this manner, the wire bonding process can be applied efficiently.

The encapsulation layer 19 is disposed on the LED chip 12, to cover the LED chip 12, as well as part of the positive electrode 17a, part of the negative electrode 17b, and the two wires 18. The encapsulation layer 19 is arc-shaped in this embodiment.

The encapsulation layer 19 is configured for optically adjusting (e.g., diverging or converging) a direction of the light emitted from the LED chip 12, thus adjusting an illuminating scope of the LED 10. In addition, the encapsulation layer 19 protects the LED chip 12 from contaminants. A base material (not shown) of the encapsulation layer 19 can be made of light-pervious material selected from the group consisting of resin, silicone, glass, epoxy, polyethylene terephthalate, polymethyl methacrylate, or polycarbonate. In this embodiment, the encapsulation layer 19 may further include at least one optical wavelength converting material, mixed essentially uniformly in the base material. The first optical wavelength converting material can be in the form of particles, and may include one kind of phosphor or different kinds of phosphors. The phosphor or phosphors, for example, can be red phosphor, yellow phosphor, green phosphor, or phosphors having other colors. The phosphor or phosphors may be comprised of one of sulfides, aluminates, oxides, silicates and nitrides. For example, the phosphor or phosphors may be Ca₂Al₁₂O₁₉:Mn, (Ca, Sr, Ba)Al₂O₄:Eu, CdS, CdTe, Y₃A₁₅O₁₂Ce³⁺(YAG), Tb₃Al₅O₁₂:Ce³⁺(YAG), BaMgAl₁₀O₁₇:Eu²⁺(Mn²⁺), Ca₂Si₅N₈:Eu²⁺, (Ca, Sr, Ba)S:Eu²⁺, (Mg, Ca, Sr, Ba)₂SiO₄:Eu²⁺, (Mg, Ca, Sr, Ba)₃Si₂O₇:Eu²⁺, Y₂O₂S:Eu³⁺, Ca₈Mg(SiO₄)₄Cl₂:Eu²⁺, (Sr, Ca, Ba)SiₓO_{y}N_{z}:Eu²⁺, (Ca, Mg, Y)SiwAlₓO_{y}N_{z}:Eu²⁺, or CdSe.

In operation, electric current is applied to the LED chip 12, whereby the LED chip 12 emits light to an ambient environment through the encapsulation layer 19. The heat sink 11 dissipates the heat generated by the LED chip 12 to the outside of the LED 10. In this manner, the LED chip 12 may operate continually within an acceptable temperature range to achieve stable optical performance, and the brightness and the luminous efficiency of the LED 10 are stably maintained.

One advantage of the LED 10 is that the positive electrode 17a and the negative electrode 17b are thermally and electrically insulated from the heat sink 11 by the insulating layer 15. Heat dissipated from the LED chip 12 and electric current applied to the LED chip 12 are through two independent paths and may not affect each other. Therefore, the LED 10 emits light efficiently as well as dissipates heat efficiently.

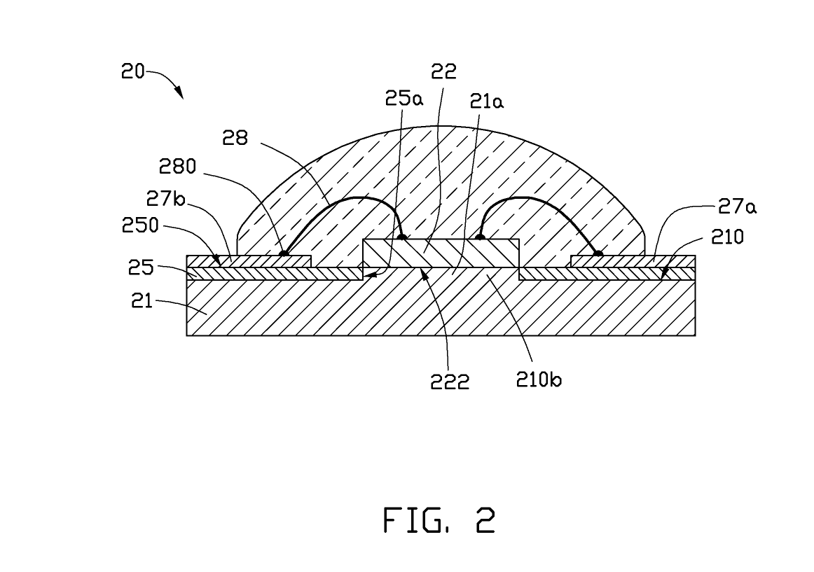

Referring to FIG. 2, an LED 20, in accordance with a second embodiment, is shown. The LED 20 is similar to the LED 10 in the first embodiment and includes a heat sink 21 having a first surface 210, an LED chip 22, an insulating layer 25, a positive electrode 27a, and a negative electrode 27b. Overall, the LED 20 differs from the LED 10 in that the heat sink 21 of the LED 20 further includes a protruding portion 21a protruding from a second portion 210b of the first surface 210. The protruding portion 21a is received in a hole 25a of the insulating layer 25. The LED chip 22 is attached to the protruding portion 21a. A bottom surface 222 of the LED chip 22 is coplanar with a second surface 250 of the insulating layer 25. Thus, the insulating layer 25 can be formed on the heat sink 21 by applying screen printing easily. In this embodiment, two distal ends 280 of each wire 28 are not necessarily the same height relative to the third surface 250. In stead, the distal end 280 of the wire 28 bonded to the LED chip 22 is relatively higher than the other distal end 280 bonded to either of the positive electrode 27a and the negative electrode 27b.

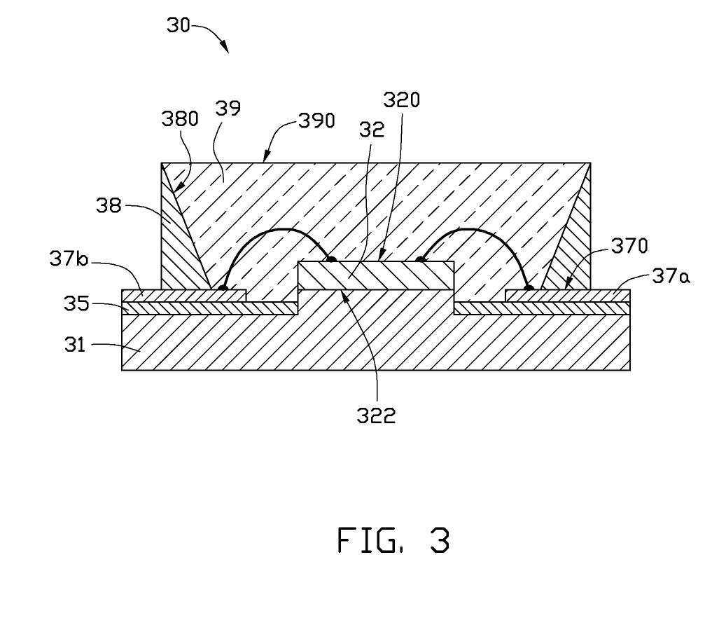

FIG. 3 illustrates an LED 30 according to a third embodiment. The LED 30 is similar to the LED 20 in the second embodiment, and includes a heat sink 31, an LED chip 32, an insulating layer 35, a positive electrode 37a, a negative electrode 37b, and an encapsulation layer 39. However, for the LED 30, a bottom surface 322 of the LED chip 320 is coplanar with a third surface 370 of the positive electrodes 37a and a third surface 370 of the negative electrodes 37b. The LED 30 further includes a molding cup 38 arranged on a side of the insulating layer 35 facing away from the heat sink 31. The molding cup 38 covers part of the positive electrode 37a and part of the negative electrode 37b, and surrounds an LED chip 32. In this embodiment, the molding cup 38 has a reflective surface 380 surrounding the LED chip 32. The encapsulation layer 39 covers the reflective surface 380 and encapsulates the LED chip 32. In addition, the encapsulation layer 39 includes an output surface 390 adjoining the reflective surface 380 and facing a light emitting surface 320 of the LED chip 32. The LED chip 32 emits light from the light emitting surface 320. The light transmits in the encapsulation layer 39 and passes all the way through the output surface 390 to an ambient environment.

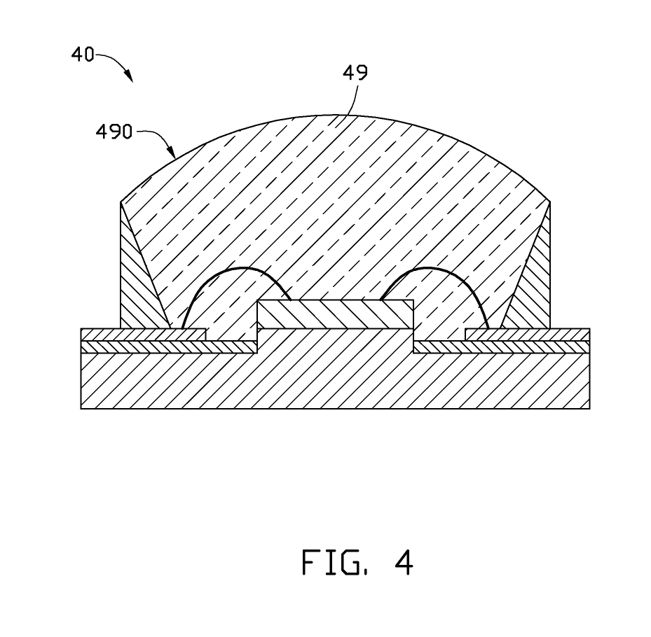

In this embodiment, the output surface 390 of the encapsulation layer 39 is a plane surface. In alternative embodiments, for example, an encapsulation layer 39 of an LED 40 in accordance with a fourth embodiment may include an output surface 490 having another suitable shape, such as an arc-shaped surface, as shown in FIG. 4.

The disclosure further relates to a light source module using the LEDs 10, 20, or 30 from the first, the second, or the third embodiments. For example, a light source module 50 in accordance with a fourth embodiment using the LED 30 from the third embodiment, as shown in FIG. 4, is described below.

The light source module 50 includes a circuit board 52, a number of LEDs 30 mounted on the circuit board 52, and a heat dissipation device 54 connected to the LEDs 30. In this embodiment, the light source module 50 includes three LEDs 30.

The LEDs 30 according to this embodiment all have a same structure as the LED 30 from the third embodiment. Therefore, for the purpose of brevity, the LEDs 30 in this embodiment are not further described herein with the understanding that like reference numbers of the LED 30 in the third embodiment refer to like parts in the LEDs 30 in this embodiment. The LEDs 30 in this embodiment are used as a light source for illumination. In alternative embodiments, the LEDs in this embodiment can be the LEDs 10 from the first embodiment and/or the LEDs 20 from the second embodiment.

The heat dissipation device 54 is configured to dissipate heat from the LEDs 30. In this embodiment, the heat dissipation device 54 includes a base 540 connecting the heat sinks 31 of the LEDs 30, and a number of fins 542 extending from the base 540 and facing away from the LEDs 30. The base 540 includes a base surface 5400 contacting the heat sinks 31 of the LEDs 30. In particular, the LEDs 30 can be attached to the base 540 by an adhesive layer (not shown). The adhesive layer can be coated on either or both of the bottom surfaces 312 and the base surface 5400, before the LEDs 30 are attached to the base 540. The LEDs 30 are spaced from one another. Accordingly, two gaps 300 are formed between each two neighboring LEDs 30. The heat dissipation device 54 may further include two extending portions 546 extending from the base surface 5400. The extending portions 546 can be partially engaged in the respective gaps 300 without contacting the circuit board 52. In operation, heat from the LEDs 30 can be transferred to the fins 542 through the base 540. The fins 542 increase the surface area contacting the air. Thus, if there is a need, more heat can be dissipated to the air.

The circuit board 52 can be a ceramic circuit board. In this embodiment, the circuit board 52 is a flexible printed circuit board (FPCB). A base material of the circuit board 52 can be polyester (PET), polyimide (PI), polyethylene naphthalate (PEN), epoxy, or fiberglass, or another suitable material.

The circuit board 52 includes a fourth surface 520 and an opposite fifth surface 522 at two opposite sides thereof. In this embodiment, the circuit board 52 has three through holes 524 defined in the fourth surface 520 for allowing the molding cups 38 and the encapsulation layers 39 of the respective LEDs 30 to extend therethrough. In mounting the LEDs 30 on the circuit board 52, the positive electrode 37a and the negative electrode 37b of each LED 30 are attached to the circuit board 52 by an adhesive layer (not shown). The adhesive layer can be coated on either or both of the third surface 370 and the fifth surface 522, before the LEDs 30 are attached to the circuit board 52. The adhesive layer may be made of metallic material selected from the group consisting of gold, tin, and silver; or the adhesive layer may be colloidal silver, or solder paste, or another suitable adhesive material.

The circuit board 52 generally includes a power supply (not shown) to apply electric current to each of the LEDs 30 via the positive electrodes 37a and the negative electrodes 37b. In this embodiment, the circuit board 52 is thermally and electrically insulated from the heat sinks 31 and the heat dissipation device 54 by the insulating layers 35. Heat generated from the LEDs 30 and electric current applied to the LEDs 30 may not affect each other. Therefore, light source module 50 emits light efficiently as well as dissipates heat efficiently.

It is believed that the embodiments and their advantages will be understood from the foregoing description, and it will be apparent that various changes may be made thereto without departing from the spirit and scope of the disclosure or sacrificing all of its material advantages, the examples hereinbefore described merely being preferred or embodiments of the disclosure.

What is claimed is:

1. A light emitting diode comprising:
a heat sink having a first surface, the first surface comprising a first portion and a second portion adjacent to the first portion;
at least one insulating layer arranged on the first portion of the first surface and having at least one second surface facing away from the heat sink;
a positive electrode and a negative electrode arranged on the at least one second surface of the insulating layer, the positive electrode and the negative electrode each having a third surface facing away from the at least one insulating layer; and
a light emitting diode chip mounted on the second portion of the first surface and spaced from the positive electrode and the negative electrode, the light emitting diode chip electrically connected to the positive electrode and the negative electrode.

2. The light emitting diode of claim 1, wherein the first portion surrounds and adjoins the second portion.

3. The light emitting diode of claim 2, wherein the at least one insulating layer comprises an insulating layer, and the insulating layer is annular and surrounds the light emitting diode chip.

4. The light emitting diode of claim 2, wherein the at least one insulating layer comprises two insulating layers spaced from each other, the positive electrode and the negative electrode are arranged on the respective insulating layers.

5. The light emitting diode of claim 4, wherein the light emitting diode chip comprises a light emitting surface facing away from the second portion, the light emitting surface is coplanar with the third surface, and two wires are provided to electrically connecting the light emitting diode chip to the respective positive electrode and negative electrode, each of the wires comprises two distal ends bonded to the light emitting surface and the third surface of the corresponding positive electrode or negative electrode.

6. The light emitting diode of claim 2, wherein the first portion and the second portion are coplanar.

7. The light emitting diode of claim 1, wherein the second portion of the first surface is a protruding portion of the first surface, and the light emitting diode comprises a bottom surface attached to the protruding portion, the bottom surface being coplanar with the second surface.

8. The light emitting diode of claim 1, wherein the heat sink is made of metallic material selected from the group consisting of aluminum, copper, and aluminum-copper alloy.

9. The light emitting diode of claim 1, wherein the at least one insulating layer is made of material selected from the group consisting of polyester, polyimide, polycarbonate, polymethyl methacrylate, polymer, silicone, epoxy, spin on glass, silicon oxide, silicon nitride, silicon oxynitride, titanium dioxide, titanium nitride, and aluminum oxide.

10. A light source module, comprising:
at least one light emitting diode, comprising:
a heat sink having a first surface, the first surface comprising a first portion and a second portion adjacent to the first portion,
at least one insulating layer arranged on the first portion of the first surface and having at least one second surface facing away from the heat sink,
a positive electrode and a negative electrode arranged on the at least one second surface of the insulating layer, the positive electrode and the negative electrode each having a third surface facing away from the at least one insulating layer, and
a light emitting diode chip mounted on the second portion of the first surface and spaced from the positive electrode and the negative electrode, the light emitting diode chip electrically connected to the positive electrode and the negative electrode; and
a circuit board coupled to the positive electrode and the negative electrode, and the circuit board having at least one through hole defined therein for allowing light of the at least one light emitting diode passing therethrough; and
a heat dissipation device coupled to an opposite side of the heat sink in respect to the circuit board.

11. The light source module of claim 10, wherein the heat dissipation device comprising a base contacting the heat sink and a plurality of fins extending from the base.

12. The light source module of claim 11, wherein the at least one light emitting diode comprises a plurality of light emitting diodes spaced from one another, with a plurality of gaps being formed between each two neighboring light emitting diodes, and the heat dissipation device further comprises a plurality of extending portions extending from the base, the extending portions being partially engaged in the respective gaps without contacting the circuit board.

13. The light source module of claim 10, wherein the circuit board comprises a flexible printed circuit board.

14. The light emitting diode of claim 10, wherein the first portion surrounds and adjoins the second portion.

15. The light source module of claim 14, wherein the at least one insulating layer comprises two insulating layers spaced from each other, the positive electrode and the negative electrode are arranged on the respective insulating layers.

16. The light source module of claim 15, wherein the light emitting diode chip comprises a light emitting surface facing away from the second portion, the light emitting surface is coplanar with the third surface, and two wires are provided to electrically connect the light emitting diode chip to the respective positive electrode and negative electrode, each of the wires comprises two distal ends bonded to the light emitting surface and the third surface of the corresponding positive electrode or negative electrode.

17. The light source module of claim 14, wherein the first portion and the second portion are coplanar.

18. The light source module of claim 10, wherein the second portion of first surface of the heat sink is a protruding portion, and the light emitting diode comprises a bottom surface attached to the protruding portion, the bottom surface being coplanar with the second surface.

19. The light source module of claim 10, wherein the heat sink is made of metallic material selected from the group consisting of aluminum, copper, and aluminum-copper alloy.

20. The light source module of claim 10, wherein the at least one insulating layer is made of material selected from the group consisting of polyester, polyimide, polycarbonate, polymethyl methacrylate, polymer, silicone, epoxy, spin on glass, silicon oxide, silicon nitride, silicon oxynitride, titanium dioxide, titanium nitride, and aluminum oxide.
